(19) United States
(12) Patent Application Publication
(10) Pub. No.: US 2026/0225876 A1
(43) Pub. Date: Aug. 6, 2026

(54) MEMS Structure with Via-based Thermistor

(71) Applicant: Stathera IP Holdings Inc., Montreal (CA)

(72) Inventors: Sebastien Lavigne, Saint-Hubert (CA); Qing Zhang, Montreal West (CA); Vahid Tayari, Montreal (CA)

(21) Appl. No.: 19/441,123

(22) Filed: Jan. 6, 2026

Related U.S. Application Data
(60) Provisional application No. 63/752,256, filed on Jan. 31, 2025.

(51) Int. Cl. B81B 7/00; B81C 1/00; G01K 7/22

(52) U.S. Cl. CPC B81B 7/0087; B81C 1/00341; G01K 7/226; B81B 2201/0271; B81B 2203/04

(57) ABSTRACT

MEMS devices with co-packaged thermistors, methods of fabrication, and methods of measuring temperature of a MEMS device are described. In an embodiment, a MEMS device with co-packaged thermistor includes a device layer which includes a resonator element, and a cap layer bonded to the device layer. In accordance with embodiments, the cap layer includes a via thermistor including a bulk via that extends through a thickness of the cap layer, a resistive plug that extends through the thickness of the cap layer; an insulator liner layer between the bulk via and the resistive plug and a conductive cap covering the plug.

### RELATED APPLICATIONS

This application claims the benefit of priority from U.S. Provisional Patent Application Ser. No. 63/752,256 filed on Jan. 31, 2025, the full disclosure of which is incorporated herein by reference.

### BACKGROUND

### Field

Embodiments described herein relate to microelectromechanical systems (MEMS), and more particularly to MEMS resonator structures.

### BACKGROUND INFORMATION

Microelectromechanical systems (MEMS) are small integrated devices or systems that combine electrical and mechanical components. The components can range in size from the sub-micrometer level to the millimeter level, and there can be any number, from one, to a few, to potentially thousands or millions, in a particular system. Some MEMS structures, in particular MEMS resonators, are hermetically sealed within low-pressure cavities to ensure consistent operation in different environments and temperature ranges. The resonance frequency of silicon MEMS resonators depends on temperature.

One of the existing challenges in designing MEMS resonators is implementing an integrated temperature sensor to be able to read the temperature and correct for the frequency shift of the resonator. One common and commercially viable method is to use a thermistor. A thermistor is a resistor that changes its resistance by temperature. Creating such a thermistor on the MEMS is challenging due to the MEMS design rule or low resistivity of the wafer stacks.

### SUMMARY

MEMS devices with co-packaged thermistors, methods of fabrication, and methods of measuring temperature of a MEMS device are described. In an embodiment, a MEMS device with co-packaged thermistor includes a device layer which includes a resonator element, and a cap layer bonded to the device layer. In accordance with embodiments, the cap layer includes a via thermistor including a bulk via that extends through a thickness of the cap layer, a resistive plug that extends through the thickness of the cap layer; and an insulator liner layer between the bulk via and the resistive plug. A first contact terminal is in electrical connection with the bulk via, and a second contact terminal is in electrical connection with the resistive plug. Electrical connection between the bulk via and the resistive plug can be made with a conductive cap that covers at least a portion of the resistive plug and a portion of the bulk via. The conductive cap may be located within an upper cavity in the cap layer that hermetically seals the resonator element. In this manner, a bottom of the via thermistor is in close proximity with the resonator element for temperature sensing. The MEMS device may additionally include a support layer with a lower cavity, where the device layer is bonded to the support layer and the resonator element is directly over the lower cavity.

In a particular configuration the bulk via can laterally surround the resistive plug. The bulk via may also be formed from the cap layer, and be formed of single crystalline silicon, which may be doped for electrical conductivity. The resistive plug in some embodiments is formed of polysilicon, which may also be doped to control the material resistivity and therefore the plug resistance. In an embodiment, the polysilicon is doped with a dopant concentration of at least 1×10¹⁹ cm⁻³. The cap that connects the resistive plug and the bulk via may also be formed of polysilicon, for example, and may be similarly doped.

A plurality of via thermistors can be serially connected in a daisy chain configuration to tune the total via thermistor resistance up to a required amount. In an embodiment, the cap layer includes a second via thermistor serially connected with the (first) via thermistor. Similarly, the second via thermistor can include a second bulk via extending through the thickness of the cap layer, a second resistive plug extending through the thickness of the cap layer, and a second insulator liner layer between the second bulk via and the second resistive plug, where the second bulk via laterally surrounds the second resistive plug. Metal trace routing on top of the cap layer can connect the via thermistor and the second via thermistor.

Additional components can also be included in the various MEMS layers. For example, the device layer can also include an in-plane capacitive drive electrode laterally adjacent to the resonator element, etc. In such a configuration, the cap layer can also include a drive electrode plug that is bonded to the in-plane capacitive drive electrode. In an embodiment, the cap layer includes an out-of-plane drive electrode directly over the resonator element. The via thermistors are compatible with a variety of configurations and driving manners. Furthermore, total resistance can be largely determined by the resistive plug dimensions and composition rather than the surrounding MEMS layer compositions. Thus, the device layer may be sufficiently doped for other purposes. For example, the device layer may be homogenously doped with a dopant concentration on an order of 10¹⁹ cm⁻³ and higher. The cap layer may also be doped, for example with a dopant concentration that is less than or equal to a dopant concentration of the device layer.

In accordance with embodiments, isolation trenches used to define other features in the cap layer can also be used to define the via thermistor. In an embodiment, the isolation trench formed through the cap layer used to define the via thermistor is filled with an interior insulator liner layer laterally adjacent to the bulk via, an exterior insulator liner layer laterally adjacent to a portion of the cap layer outside of the via thermistor, a resistive fill material between the interior insulator liner layer and the exterior insulator liner layer. In an embodiment, the resistive plug is characterized by a lateral width that is greater than a lateral width of the resistive fill material between the interior insulator liner layer and the exterior insulator liner layer. In an embodiment, the resistive plug and the resistive fill material have a same dopant concentration.

The via thermistors in accordance with embodiments, or daisy chains thereof, can be electrically connected with various terminal designs. In an exemplary four terminal design a current input is coupled with the first contact terminal and a current output can be coupled with the second contact terminal, or vice versa. In an exemplary two terminal design a voltage source can be coupled with the first contact terminal and an electrical ground is coupled with the second contact terminal, or vice versa.

In an embodiment, a method of measuring temperature of a MEMS device includes measuring voltage across a via thermistor while applying current through the thermistor, amplifying the voltage with a voltage amplifier, and feeding the amplified voltage to an analog-to-digital converter (ADC) to extract a temperature value, where the MEMS device includes a cap layer bonded to a device layer, with the cap layer including the via thermistor as described above.

### BRIEF DESCRIPTION OF THE DRAWINGS

FIG. 1 is a schematic perspective view illustration of a via thermistor in accordance with an embodiment.

FIG. 2A is a schematic perspective view illustration of a MEMS device including a pair of serially connected via thermistors in accordance with an embodiment.

FIG. 2B is a schematic top layout view illustration of a MEMS device including a pair of serially connected via thermistors in accordance with an embodiment.

FIG. 3 is a schematic cross-sectional side view illustration of a MEMS device including a pair of serially connected via thermistors in accordance with an embodiment.

FIGS. 4A-4G are schematic cross-sectional side view illustrations of a sequence of fabricating a MEMS device including a pair of serially connected via thermistors in accordance with an embodiment.

FIGS. 5-6 are composite schematic cross-sectional side view illustrations of MEMS devices with co-packaged via thermistors in accordance with embodiments.

FIG. 7 is schematic perspective view illustration of a MEMS device with a laterally supported rectangular resonator element in accordance with an embodiment.

FIGS. 8A-8B are schematic perspective view illustrations of a MEMS device with a vertically supported circular resonator element in accordance with an embodiment.

FIG. 9 is a circuit diagram for a two-terminal co-packaged via thermistor in accordance with an embodiment.

FIG. 10 is a circuit diagram for a four-terminal co-packaged via thermistor in accordance with an embodiment.

### DETAILED DESCRIPTION

Embodiments describe MEMS devices and methods of fabrication including a co-packaged via thermistor. The via thermistors in particular may be formed with materials such as silicon and polysilicon that can also be used to fill isolation trench openings that define various other structures in the MEMS devices. In this manner, the temperature-dependent structural and contact resistances of the existing materials in a MEMS device can be utilized for via thermistor integration into existing process flows. In particular, a via thermistor can be co-packaged with a resonator element to reduce thermal lag between the via thermistor and the resonator element.

In an embodiment, a MEMS device includes a device layer that includes a resonator element, and a cap layer bonded to the device layer. The cap layer can additionally include a via thermistor that is formed of a bulk via extending through a thickness of the cap layer, a resistive plug extending through the thickness of the cap layer, and an insulator liner layer between the bulk via and the resistive plug. In a particular embodiment, the resistive plug is formed within the bulk via such that the bulk via (e.g., completely) laterally surrounds the resistive plug. A first contact terminal can be in electrical contact with the bulk via while a second contact terminal is in electrical connection with the resistive plug to form a thermistor path up-and-down through the bulk via and resistive plug of the via thermistor, and vice-versa.

In accordance with embodiments, the bulk via can be formed of the same material as the cap layer, such as silicon, which may be doped. The resistive plug can be formed of a variety of fill materials such as polysilicon. The resistive plug material may be deposited in order to prevent cracks and particle contamination during downstream processing (e.g., chemical mechanical polishing slurry), while also providing a hermetic seal to a cavity in the cap layer. In some embodiments, resistivity of the resistive plug material may be lower than that of the bulk via material, yet smaller dimensions (e.g., area) of the resistive plug may increase total resistance significantly. Total system resistance can additionally be increased by connecting a plurality of via thermistors in a daisy chain (serial) connection.

By way of illustration a state-of-the-art thermistor based on an application-specific integrated circuit (ASIC) analog-to-digital converter (ADC) resolution (nominally 14-bits) may be expected to have the resistance around a few hundred to few kOhms and a few 1,000 ppm/C to be able to provide approximately 10 mK temperature noise across the temperature range. In an exemplary embodiment, a via-thermistor with polysilicon resistive plug material is fabricated in the cap layer of a hermetically sealed MEMS structure (e.g., resonator) with a phosphorous dopant concentration of about 3×10¹⁹ cm⁻³ to create a thermistor with about 2,000 ppm/C temperature coefficient to resistivity (TCR) offering 20 mK temperature resolution with 100 μA current source and 14-bits ADC. It is to be appreciated that embodiments are not limited to these specifications, and these are merely provided as an illustrative example.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

It is also to be appreciated that the figures are not necessarily drawn to scale, and that the thermistors can be integrated with a variety of MEMS devices, such as any bulk acoustic wave (BAW) or surface acoustic wave (SAW) resonator, etc. The resonators can be capacitively-transduced resonators and/or piezoelectrically-transduced resonators. Different configurations with different electrode arrangements may be implemented without departing from the embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

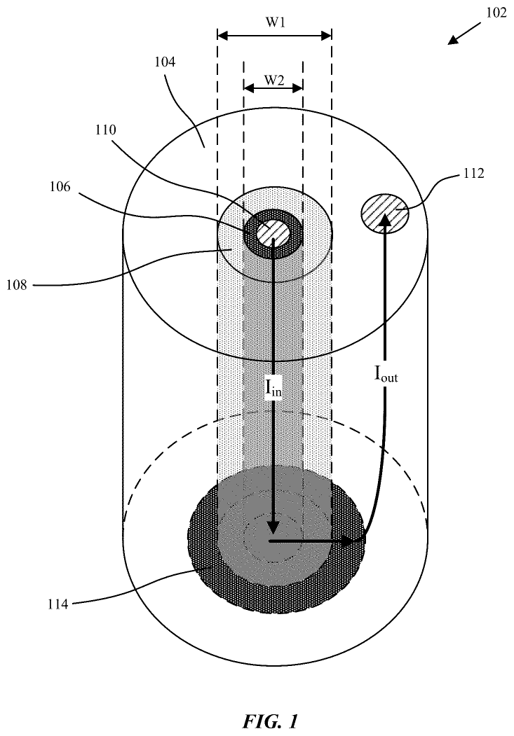

Referring now to FIG. 1, a schematic perspective view illustration is provided of a via thermistor 102 in accordance with an embodiment. As shown, the via thermistor 102 can include a bulk via 104, a resistive plug 106, and an insulator liner layer 108 laterally between the bulk via 104 and the resistive plug 106. In the illustrated embodiment, an electrical contact area 110 is made with the resistive plug 106, and an electrical contact area 112 is made with a portion of the bulk via 104 for current input and output, and vice versa. The electrical contact areas 110, 112 can be established with a variety of fabrication techniques, such as the formation of via landings, contact pads, etc. Furthermore, a conductive cap 114 can be deposited on an underside of the resistive plug 106 and bulk via 104, as well as the insulator liner layer 108 to provide an electrical path between the resistive plug 106 and the bulk via 104. The conductive cap 114 can be formed of suitable materials that provide an electrically conductive path and can withstand the thermal budget of the fabrication sequence, such as the cap layer bonding process. Exemplary materials include polysilicon, metallic films, etc.

In an exemplary configuration, the bulk via 104 is patterned into another layer of a MEMS device, such as a cap layer. As, such the bulk via 104 may be formed of single crystalline silicon and may be doped, in particular where electrical connections and/or out-of-plane electrodes are formed within the cap layer. The insulator liner layer 108 may be formed of a suitable material such as, but not limited to, silicon oxide (e.g., SiO₂) and silicon nitride that can be deposited or grown from the material forming the bulk via 104. The resistive plug 106 may be formed of a doped or undoped material that is deposited using a suitable conformal deposition technique such as low pressure chemical vapor deposition (LPCVD) to completely fill the available volume. In a particular embodiment, the resistive plug 106 is formed of doped or undoped polysilicon though it is possible other materials could also be utilized. Additionally, the bulk via 104 may (completely) laterally surround the resistive plug 106.

Total resistance of the one via thermistor 102 in accordance with embodiments can be dominated by resistance of the resistive plug 106. Specifically, total resistance may be determined by equation (1):

$$Rtotal = Rplug + Rbulk \qquad ( 1 )$$

where Rtotal is total resistance, Rplug is resistance of the resistive plug 106, and Rbulk is resistance of the bulk via 104. Similarly, resistance of each component can be proportional to length (e.g., thickness) and area (e.g., lateral). For example, Rplug is calculated as shown in equation (2):

$$Rplug ∝ ( ρ * l ) / A \qquad ( 2 )$$

wherein l is length of the resistive plug, A is area of the resistive plug, and ρ is the resistivity of the resistive plug. In an exemplary implementation length (or thickness of the cap layer) is approximately 100 μm, width of the resistive plug (W2) is approximately 5 μm, and width across the resistive plug and liner layers (W1) is approximately 9 μm. Thus, the liner layer 108 may be approximately 2 μm wide. The bulk via 104 width may be substantially wider than the resistive plug width. With reference to equation (2) applied to the bulk via, since the area of the bulk via 104 is much greater than the area of the resistive plug 106, it is determined that Rplug>>Rbulk. Therefore, Rplug may be the main contributor to Rtotal of the via thermistor 102. Both physical dimensions and resistivity of the resistive plug can be adjusted to achieve desired total resistance target. In accordance with some embodiments the resistive plug is deposited by LPCVD to provide accurate resistivity to the polysilicon. In some embodiments, the polysilicon is doped with a dopant concentration (e.g., phosphorous) of at least 1×10¹⁹ cm⁻³ to achieve a temperature coefficient of resistivity of greater than 1,000 ppm/K and a total via thermistor resistance of 750-1,250 ohms.

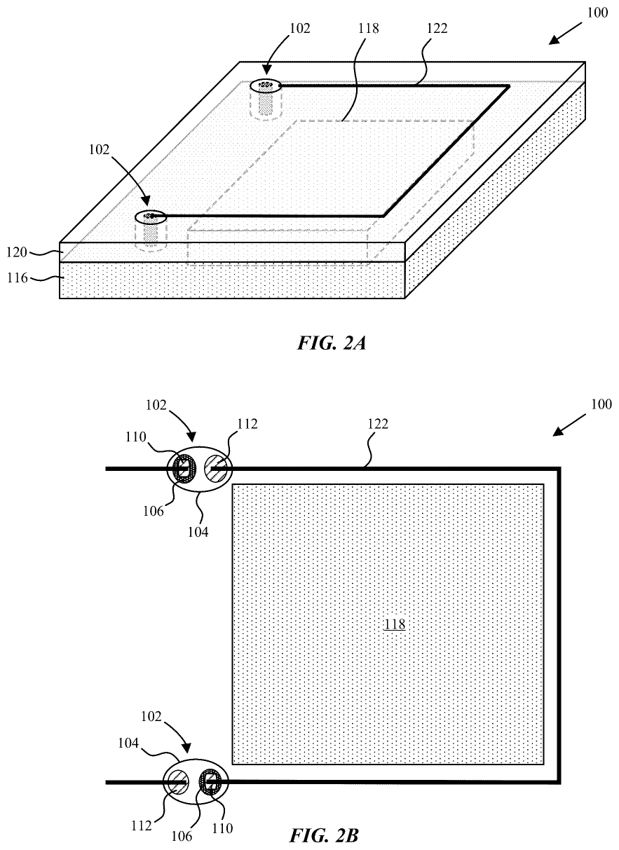

FIG. 2A is a schematic perspective view illustration of a MEMS device 100 including a pair of serially connected via thermistors 102 in accordance with an embodiment. As shown, the MEMS device 100 can include a device layer 116 that includes a resonator element 118 and a cap layer 120 bonded to the device layer 116. The cap layer 120 can include one or more via thermistors 102 that are patterned through a thickness of the cap layer 120. The plurality of via thermistors 102 can be electrically connected with a metal trace routing 122 formed on top of the cap layer 120.

Up until this point the via thermistors 102 have been illustrated as cylindrical in shape, though this is not required. The via thermistors 102 may assume a variety of shapes to provide a current path through the resistive plug 106 and bulk via 104. FIG. 2B is a schematic top layout view illustration of a MEMS device including a pair of serially connected via thermistors in accordance with an embodiment. FIG. 2B is substantially similar to the exemplary layout illustrated in FIG. 2A, with the via thermistors 102 having an oblong, or elliptical configuration. It is to be appreciated that this is exemplary, and a variety of configurations are contemplated, including those where the bulk via 104 does not laterally surround the resistive plug 106.

As shown in FIG. 2B, an electrical contact area 110 is made with each resistive plug 106, and an electrical contact area 112 is made with a portion of each bulk via 104. An electrical trace routing 122 can additionally serially connect the electrical contact area 112 of a first via thermistor 102 to the resistive plug 106 of a second via thermistor 102, and vice versa, so that a plurality of via thermistors 102 can be serially connected in a daisy chain configuration. In operation, the daisy chain connections of resistive plugs 106 can be utilized to tune the total thermistor resistance up to the required amount based on analog-to-digital-conversion (ADC) matching.

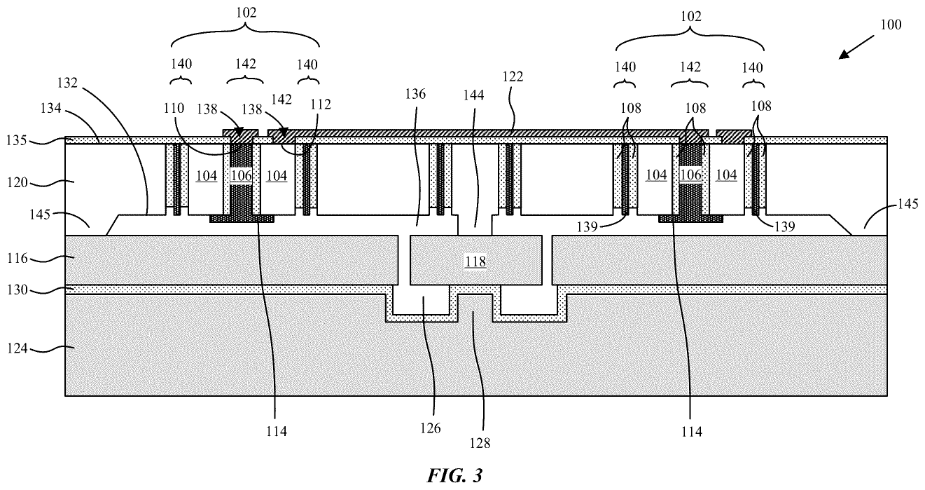

FIG. 3 is a schematic cross-sectional side view illustration of a MEMS device 100 including a pair of serially connected via thermistors 102 in accordance with an embodiment. FIG. 3 is substantially similar to the exemplary layouts illustrated in FIG. 2A-2B.

Generally, the MEMS devices in accordance with embodiments can include resonator elements that are suspended within a hermetically sealed cavity that is maintained at low pressure, and a co-packaged thermistor. It is to be appreciated that the figures are composite schematic cross-sectional side view illustrations that illustrate various features together in the same illustration, while actual arrangements when viewed from above may be different. It is also to be appreciated that the figures are not necessarily drawn to scale, and that the thermistors can be integrated with a variety of MEMS devices, such as any bulk acoustic wave (BAW) or surface acoustic wave (SAW) resonator, etc. The resonators can be capacitively-transduced resonators and/or piezoelectrically-transduced resonators. Different configurations with different electrode arrangements may be implemented without departing from the embodiments. For sake of clarity, electrode configurations are not illustrated in FIG. 3.

As shown, the MEMS device 100 can include a support layer 124, a device layer 116 and cap layer 120. The support layer 124 may be formed of any suitable handle substrate such as glass, silicon, etc. For example, the support layer 124 may be a bulk silicon substrate, or a multiple layer substrate such as silicon on insulator (SOI) substrate. As shown, the support layer 124 can be patterned to include a lower cavity 126, e.g., 5-50 μm recess, and optionally one or more anchors 128. An insulator layer 130, such as silicon oxide, may be formed (including grown or deposited) over the top side (top surface) of the support layer 124 to provide electrical insulation from subsequently bonded layers. A device layer 116 may then be bonded to the support layer 124, for example with fusion bonding a silicon-silicon oxide interface. The device layer 116 may also be a silicon substrate, which may be pre-processed to include various MEMS structures or processed after wafer bonding. Exemplary MEMS structures include resonators, humidity sensors, gas sensors, accelerometers, etc.

The device layer in accordance with embodiments may be homogenously doped with a dopant concentration on an order of 10¹⁹ cm⁻³ and higher, for example. In the particular embodiment illustrated the device layer 116 may be approximately 5-100 μm thick, and is patterned to include a resonator element 118 that is optionally supported by anchor 128. While the resonator element 118 is illustrated as being vertically supported by one or more anchors 128, the device layer 116 can alternatively include one or more tethers connected to the resonator element 118 and/or one or more side anchors to laterally support the resonator element 118 and suspend the resonator above the lower cavity 126.

A cap layer 120 (e.g., patterned silicon wafer) can be bonded to (e.g., directly to) the device layer 116, such as with fusion bonding to create silicon-silicon bonds, or alternatively with metal-metal bonding such as with eutectic bonding. The bottom side 132 of the cap layer 120 can be patterned to form an upper cavity 136, one or more walls 145 for bonding to the device layer 116 and hermetically sealing of the upper cavity 136, and optionally one or more anchors 144. The anchors 144 may be separate protrusions/mesas for contact to various structures the device layer 116. Only a single anchor 144 is illustrated in FIG. 3 in order to not obscure illustration of the via thermistors 102. Furthermore, one or more isolation trenches 140 can be patterned into the cap layer 120 to define one or more bulk vias 104, among other structures that may be attached to the anchors 144, for example. Additionally, one or more plug trenches 142 can be patterned into the cap layer 120. The plug trenches 142 may be laterally adjacent to the bulk vias 104, or be completely laterally surrounded by a corresponding bulk via 104 as shown. As shown, the isolation trenches 140 and plug trenches 142 can completely extend through a thickness of the cap layer 120 from the bottom side 132 to a top side 134.

Each isolation trench 140 may be partially or completely filled with a liner layer 108, such as silicon oxide or silicon nitride, and may optionally be filled with a filler material 139, which can be anything conformal such as polysilicon. As shown, an interior liner layer 108 within the isolation trenches 140 is laterally adjacent to the bulk via 104, and an exterior liner layer 108 is laterally adjacent to a portion of the cap layer 120 outside of the via thermistor 102.

As will become apparent in the following description, a variety of structures can be patterned into the cap layer with similarly filled isolation trenches. In accordance with embodiments, the plug trenches 142 may be patterned and filled along with the isolation trenches 140. For example, the liner layers 108 may be simultaneously formed within the plug trenches 142 and isolation trenches. Furthermore, the resistive plugs 106 may optionally be simultaneously formed with the filler material 139, with the same composition and doping, though this is not required.

As shown, internal via thermistor 102 connection between the bulk vias 104 and resistive plugs 106 may be made with a conductive cap 114 covering and spanning at least a portion of the resistive plug and a portion of the bulk via along the bottom side 132 of the cap layer 120. For example, the conductive cap 114 can be a polysilicon cap. The conducive cap 114 may additionally be doped similarly as the resistive plug 106. The conductive cap 114 can be formed of suitable materials that provide a conductive path and can withstand the thermal budget of the fabrication sequence, such as the cap layer bonding process. Exemplary materials include polysilicon, metallic films, etc. As shown, the conductive cap is within the upper cavity 136 in the cap layer 120, and the resonator element 118 is between the lower cavity 126 and the upper cavity 136.

Connection between adjacent via thermistors 102 may be made with metal trace routing 122 on top of the cap layer 120. As shown, one or more passivation layers 135 such as oxide and/or nitride layer(s) can be formed over the top side 134 of the cap layer 120, and patterned to form openings over the bulk vias 104 and resistive plugs 106 of the via thermistors 102. In the illustrated embodiment, electrical contact terminals 138 (e.g., via landings) of the metal trace routing 122 can be formed in the corresponding openings in the passivation layer(s) 135, where the area contact of the electrical contact terminals 138 (e.g., via landings) correspond to the electrical contact area 110 made with the resistive plug 106, and electrical contact area 112 made with the bulk via 104 for current input and output, and vice versa. This can be followed by additional back-end-of-the-line (BEOL) processing.

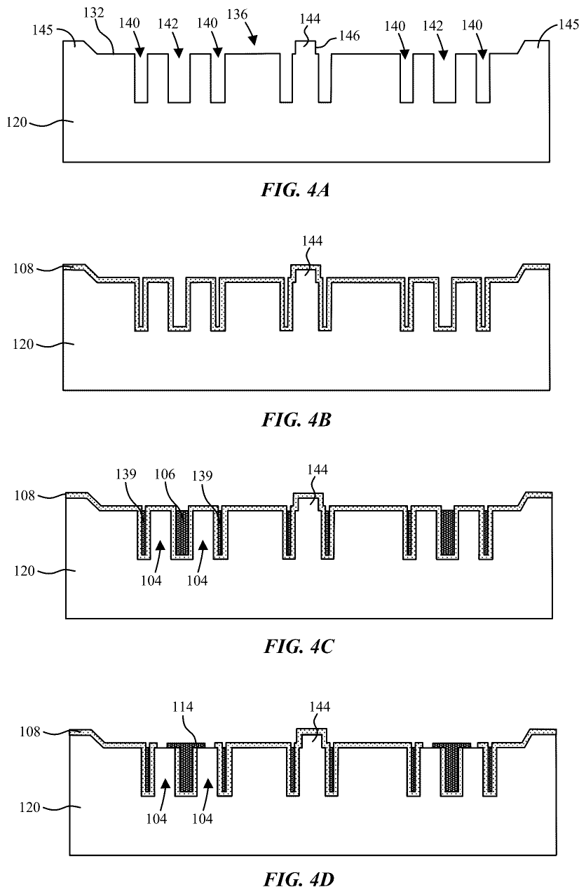

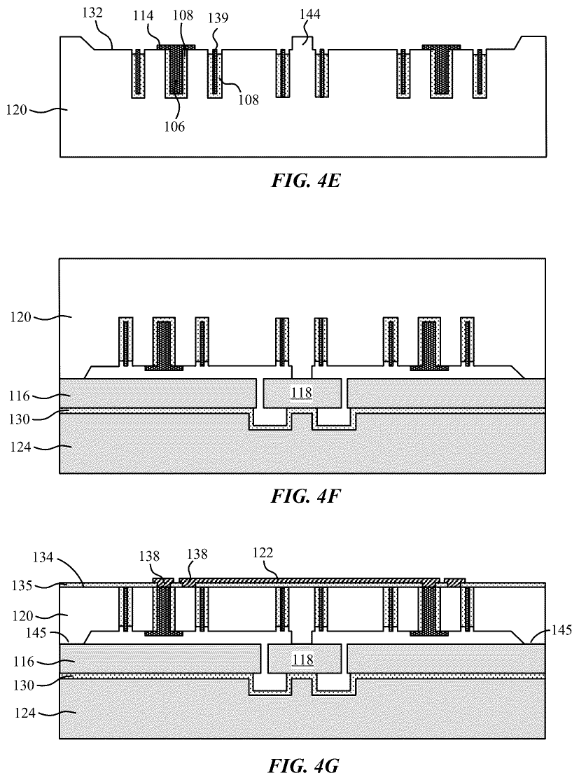

FIGS. 4A-4G are schematic cross-sectional side view illustrations of a sequence of fabricating a MEMS device including a pair of serially connected via thermistors in accordance with an embodiment. In particular, the processing sequence focuses on the fabrication of the cap layer and associated via thermistors. As shown in FIG. 4A, the illustrated process flow begins with a cap layer 120, which may be a silicon wafer. A pattern of upper cavities 136 can be formed in the cap layer 120 together with a plurality of anchors 144. While straight sidewalls 146 are illustrated, it is to be appreciated that the sidewalls 146 may be angled, and may be faceted along specific crystal planes depending upon etching technique/composition and crystal structure and orientation of the cap layer 120, or may be smeared, as in the case of a local oxidation of silicon (LOCOS) process. The anchors 144 may be utilized to make contact with the device layer, such as during bonding. As shown in FIG. 4A, isolation trenches 140 and plug trenches 142 are then etched into the cap layer 120. A liner layer 108 material such as silicon oxide can be initially grown or deposited over the bottom side 132 and along sidewalls of the anchors 144, isolation trenches 140 and plug trenches 142. This can be followed by deposition or growth of a filler material 139 and resistive plug 106, such as polysilicon, to completely fill the isolation trenches 140 and plug trenches 142 as shown in FIG. 4C in order to prevent cracks and particle contamination within the during downstream processing (e.g., chemical mechanical polishing slurry).

For example, the liner layer 108 may be formed using a thermal oxidation technique over the exposed surface of the cap layer 120 (wafer) to form a uniform silicon oxide layer that forms an outline of the exposed topography. It is to be appreciated that while topographies of various patterned surfaces are illustrated as being right angles, that this can be for ease of illustration and that various sidewalls may be angled or tapered. For example, the isolation trenches 140 and plug trenches 142 can be slanted or tapered to avoid pinching of the lining layer 108 at the bottom side 132, and avoid the formation of keyholes, voids and partial filling with the filler material 139 and resistive plug 106.

The filler material 139 and resistive plug 106 may be chosen to have a highly conformal CVD process, in order to ensure a complete fill without introducing keyholes (thus making small molecule diffusion into the cavity easier). Composition and doping of the filler material 139 and resistive plug 106 can be selected to achieve a specified resistivity. The filler material 139 and resistive plug 106, may be the same or different materials, and may be polysilicon material in an embodiment, though it is possible other materials could also be utilized. The filler material 139 and resistive plug 106 may be deposited to fill a specified height of the isolation trench 140 opening, with consideration of additional thickness of the liner layer 108.

Referring to FIG. 4D the liner layer 108 and isolation trenches 140 can then be masked while the liner layer is removed from over the resistive plugs and a portion of the cap layer 120 that will become the bulk vias 104 of the via thermistors. Conductive caps 114, such as polysilicon, are then deposited or grown to provide electrical connection between the bulk vias 104 and resistive plugs 106. The mask layer can then be removed.

Referring to FIG. 4E, the liner layer 108 may then be removed from the bottom side 132 of the cap layer 120 leaving behind separate liner layers 108 along sidewalls of the isolation trenches 140 and plug trenches 142. For example, a suitable etching technique selective to liner layer 108 may be employed. Batch wet processes may be preferrable for higher processing throughput, such as HF for silicon oxide as the liner layer 108. This partially processed cap layer 120 (wafer) can then be bonded to a device layer 116 as shown in FIG. 4F, such as with fusion bonding to create silicon-silicon bonds. The space between the bottom side 132 of the cap layer 120 and device layer 116 can form the upper cavity 136, where the resonator element 118 is hermetically sealed in the cavity volume defined by the upper cavity 136 and lower cavity 126.

Referring to FIG. 4G, a grinding (and polishing) operation may then be performed to reduce a thickness of the cap layer 120 and reveal the filled isolation trenches 140 and plug trenches 142. This can be considered a via reveal operation where vias (e.g., bulk vias 104 and resistive plugs 106) are defined by a contour of laterally surrounding isolation trenches 140 and plug trenches 142. In accordance with embodiments, the grinding operation creates a planarized top surface formed of (and spanning) the top side 134 of the cap layer 120 and the top side of the of the exposed liner layer 108, resistive plug 106, and filler material 139. At this stage BEOL processing can be formed over the planarized surface to provide electrical routing, passivation as described with regard to FIG. 3. Further processing may then be performed, such as bonding to an integrated circuit wafer and/or singulation of multiple MEMS devices from the stacked wafer structure.

Up until this point MEMS devices 100 and fabrication sequences have been described with particular regard to the formation of the via thermistors 102 within a cap layer 120 that is bonded to a device layer 116 that includes a resonator element 118 without reference to operation of the resonator element 118 and other possible surrounding features and connections within the cap layer 120 and device layer 116.

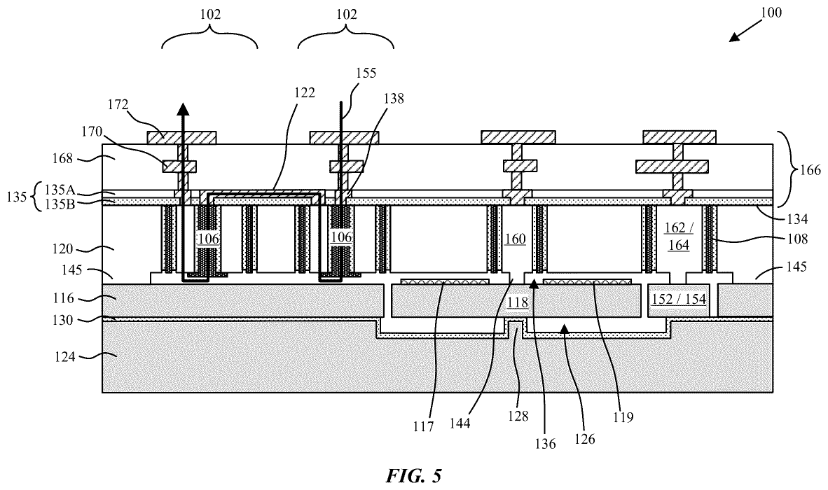

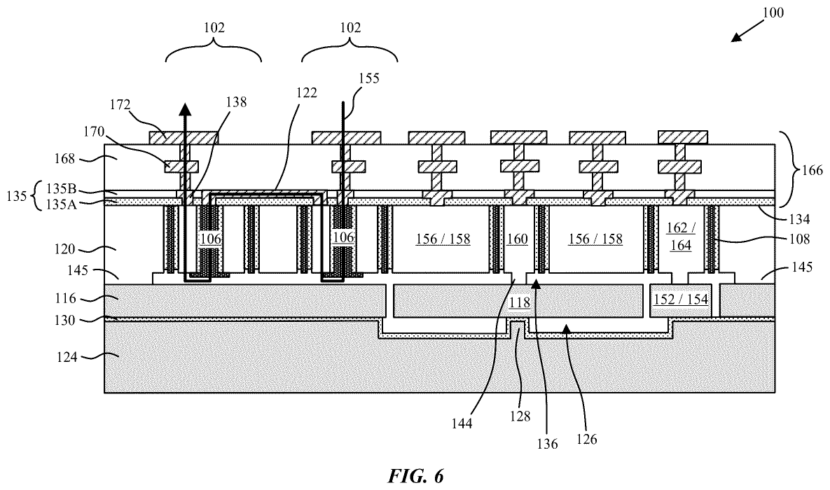

Referring now to FIGS. 5-6, composite schematic cross-sectional side view illustrations are provided of MEMS devices 100 with co-packaged via thermistors 102 in accordance with embodiments. Generally, the MEMS devices in accordance with embodiments can include resonator elements 118 that are suspended within a hermetically sealed cavity that is maintained at low pressure, and a co-packaged thermistor. It is to be appreciated that the figures are composite schematic cross-sectional side view illustrations that illustrate various features together in the same illustration, while actual arrangements when viewed from above may be different. It is also to be appreciated that the figures are not necessarily drawn to scale, and that the thermistors can be integrated with a variety of MEMS devices, such as any bulk acoustic wave (BAW) or surface acoustic wave (SAW) resonator, etc. The resonators can be capacitively-transduced resonators and/or piezoelectrically-transduced resonators. Different configurations with different electrode arrangements may be implemented without departing from the embodiments.

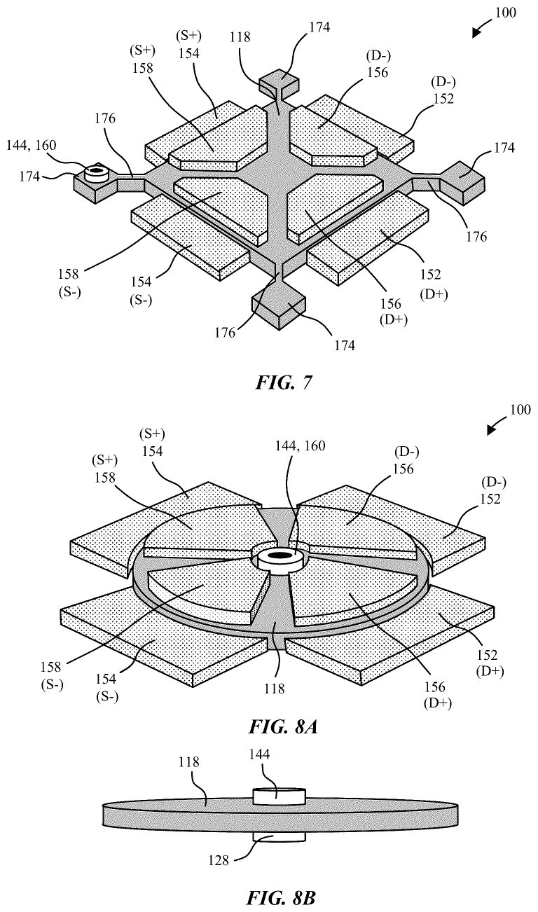

As shown, the MEMS devices 100 can include a support layer 124, a device layer 116 and cap layer 120 as previously described. The device layer in accordance with embodiments may be homogenously doped with a dopant concentration on an order of 10¹⁹ cm⁻³ and higher, for example. The device layer 116 may include additional structures, such as in-plane drive electrodes 152 and in-plane sense electrodes 154, for example. While a single in-plane drive electrode 152 or in-plane sense electrode 154 is illustrated, it is understood that one or more of the in-plane drive electrodes 152 and in-plane sense electrodes 154 may be arranged laterally adjacent to the resonator element 118. Additionally, while the resonator element 118 is illustrated as being vertically supported by one or more anchors 128, 144, the device layer 116 can alternatively include one or more tethers connected to the resonator element 118 and/or one or more side anchors (e.g., see FIG. 7) to laterally support the resonator element 118 and suspend the resonator element within the upper and lower cavities.

Cap layer 120 (e.g., patterned silicon wafer) can be bonded to (e.g., directly to) the device layer 116, such as with fusion bonding to create silicon-silicon bonds, or alternatively with metal-metal bonding such as with eutectic bonding. Anchors 144 can be bonded to various MEMS structures within the device layer 116, such as the resonator element 118, in-plane drive electrodes 152 and in-plane sense electrodes 154, side anchors, etc. In an exemplary embodiment illustrated in FIG. 6, patterned areas between the anchors 144 can be positioned over the resonator element 118 to define area for capacitive out-of-plane drive electrodes 156 and/or out-of-plane sense electrodes 158. The height of the upper cavity 136 can optionally define an out-of-plane transduction gap when capacitive out-of-plane drive electrodes 156 and/or out-of-plane sense electrodes 158 are included.

Both in-plane and out-of-plane resonance may also be achieved using piezoelectric transduction as shown in FIG. 5 where piezoelectric drive electrodes 117 and piezoelectric sense elections 119 can be formed of stacked piezoelectric layers and metal layers on the resonator element 118 and connected to via plugs in the cap layer and corresponding electrical contact terminals, for example with metal wiring spanning over tethers connected to the resonator element.

Various structures may be defined by the isolation trenches 140, such as resonator plug 160 optionally provide mechanical support for the resonator and/or provide a bias voltage to the resonator element 118, drive electrode plug(s) 162 and sense electrode plug(s) 164 to transfer a voltage to in-plane drive electrode(s) 152 and in-plane sense electrode(s) 154, as well as optional out-of-plane drive electrode(s) 156 and out-of-plane sense electrode(s) 158. Drive electrode plug(s) and sense electrode plug(s) can also be connected to the piezoelectric drive electrode(s) 117 and piezoelectric sense electrode(s) 119 (e.g., to a metal wiring layer spanning over tethers and side anchors) for in-plane and/or out-of-plane resonance.

At this stage BEOL processing can be formed over the planarized surface to provide electrical routing and passivation. Further processing may then be formed, such as bonding to an integrated circuit wafer and/or singulation of multiple MEMS devices from the stacked wafer structure.

As shown, the BEOL build-up structure 166 may include one or more passivation layers 135, such as passivation layers 135A, 135B. In an embodiment the first passivation layer 135A is a single layer or multiple layer stack that may be formed of one or more materials to mitigate small molecule diffusion, such as hydrogen, helium, etc. into the cavity volume. Exemplary materials include insulating materials such as silicon nitride, aluminum nitride, aluminum oxide, or silicon carbide to prevent shorting across the top surface of the cap layer 120. Additional layers can also be included such as aluminum, copper, titanium, nickel, gold, chromium, molybdenum, titanium nitride, metal silicide, polysilicon, etc. to assist in blocking diffusion. The top passivation layer 135B may be formed of a suitable dielectric material such as silicon oxide used for BEOL structures to provide electrical insulation, film quality, and deposition rate. In particular, when the passivation layer 135A is formed of a high-stress nitride that cannot be deposited thick enough to provide sufficient dielectric insulation of metal traces, adding the optional top passivation layer 135B can provide improved dielectric insulation.

Openings may then be formed through the one or more passivation layers 135 to expose the various MEMS components and/or connections followed by deposition of electrical contact terminals 138 (e.g., via landings). For example, the electrical contact terminals 138 can be formed on the resistive plug 106 and bulk via 104 of a via thermistor 102, one or more out-of-plane via drive electrodes 156, one or more out-of-plane via sense electrodes 158, and resonator plug 160, etc. Electrical contact terminals 138 can additionally be formed on one or more drive electrode plugs 162 and one or more sense electrode plugs 164 for in-plane driving and sensing.

The electrical contact terminals 138 may be formed of one or more layers including various metal layers and alloys thereof, polysilicon, etc. Selection of materials may additionally depend upon doping concentrations of the cap layer. For example, a first liner layer of heavily doped polysilicon (e.g., in-situ doped polysilicon, ISDP) can first be deposited directly onto an n-type silicon cap layer to avoid creating a p-n junction. This can be followed by depositing one or more bulk metal layers, such as copper, gold, etc. An intermediate polysilicon layer may not be necessary for making electrical contact with p-type silicon. A variety of arrangements are possible.

Additional BEOL processing can be performed following the formation of the electrical contact terminals 138, such as the formation additional dielectric layers 168 and wiring layers 170 connected to chip contact pads 172.

In accordance with embodiments, one or more via thermistors can optionally be connected together in a daisy chain configuration such that a serial path 155 exists from a first contact terminal 138 connected to a first via thermistor 102 to a last contact terminal 138 connected to a last via thermistor 102. In some embodiments, the serial path 155 passes through multiple metal wiring layers 170 and via connections therebetween. In the particular embodiments illustrated the serial path 155 may pass through a lower wiring layer 170 including metal trace routing 122, which may be the same layer or different layer used to form the contact terminals 138. More particularly, the path between via thermistors 102 in the serial path 155, may be confined to lower metallization layer(s) and be buried within the BEOL build-up structure 166, and underneath higher metallization layer(s) and chip contact pads 172.

Referring now to FIG. 7, an isometric view illustration is provided of a MEMS device 100 with rectangular resonator element 118 in accordance with an embodiment. As depicted, the square resonator element 118 may be part of a capacitively-transduced Lamé mode resonator including a pair of in-plane drive electrodes 152 denoted by D+/D− and a pair of in-plane sense electrodes 154 denoted by S+/S−, disposed around its periphery whilst the resonator element 118 itself is direct current (DC) biased through a resonator plug 160 at one or more side anchors 174. In this instance the side anchors 174 are connected to corners of the resonator element 118 with tethers 176 and are coupled to an electrical contact terminal through a resonator plug 160.

In operation, the two in-plane drive electrodes 152 are used to provide two drive signals that are 180° out of phase, as denoted D+/D−. Another set of in-plane sense electrodes 154, denoted S+/S−, are used to collect the two out of phase output signals and recombine them. A bias voltage can additionally be provided to the resonator element 118 through a resonator plug 160. Typically, this would be used for frequency tuning.

The MEMS device 100 in accordance with embodiments may additionally include out-of-plane via drive electrodes 156 and out-of-plane via sense electrodes 158. For example, the out-of-plane via drive electrodes 156 and out-of-plane via sense electrodes 158 can be positioned over a top surface of the resonator element 118 and separated by a gap distance (such as 0.05-2.0 microns) for capacitive transduction of the resonator element 118. Similar to the in-plane drive electrodes 152 and in-plane sense electrodes 154, the out-of-plane via drive electrodes 156 and out-of-plane via sense electrodes 158 can be utilized to drive and collect out of phase signals and recombine them. The resonator element 118 may further be configured such that the in-plane drive electrodes 152 excites an in-plane resonance mode, and the out-of-plane drive electrodes 156 excites an out-of-plane resonance mode in a controlled manner. Herein, “a controlled manner” refers to selectively exciting one, both or neither of the in-plane and out-of-plane resonance mode. For an in-plane resonance mode, the resonator element may be deflectable in plane into open space laterally around the resonator element. For an out-of-plane resonance mode the resonator element may be deflectable into the lower cavity and upper cavity.

It is to be appreciated that while the out-of-plane via drive electrodes 156 and out-of-plane via sense electrodes 158 are described and illustrated as being part of the cap layer, and being used for capacitive transduction, that the arrangements shown in FIG. 7 can also be achieved with piezoelectric drive electrodes 117 and piezoelectric sense elections 119 deposited onto the resonator element 118 for in-plane and/or out-of-plane resonance (e.g., as similarly illustrated for the out-of-plane via drive electrodes 156 and out-of-plane via sense electrodes 158 over the resonator element 118).

Rather than tethering the resonator element 118 to side anchors 174, the resonator element 118 can be supported by centrally located anchors. FIGS. 8A-8B are isometric view illustrations of a MEMS device circular resonator element 118 in accordance with an embodiment. In interest of clarity the various sense and drive electrodes are not illustrated in FIG. 8B. As shown, the resonator element 118 can be supported by one or more anchors 128, 144 on a bottom and/or top side of the resonator element 118. Similar to the capacitively-transduced resonator depicted in FIG. 7, the capacitively-transduced resonator depicted in FIG. 8A includes a pair of in-plane drive electrodes 152 denoted by D+/D− and a pair of in-plane sense electrodes 154 denoted by S+/S− disposed around its periphery whilst the resonator element 118 itself is DC biased through one or more anchors 144. The one or more anchors 144 may be physically connected with the resonator element 118 to provide physical support, and optionally function as a DC bias electrode. The one or more anchors 128 may also be physically connected with the resonator element 118 to provide physical support. Similar to FIG. 7, out-of-plane via drive electrodes 156 and out-of-plane via sense electrodes 158 may optionally be included above the resonator element 118 for out-of-plane driving and sensing.

In operation temperature can be extracted by applying current through the via thermistor(s) and measuring voltage across it. For example, an approximate 100 μA current with 5 millisecond pulse with and duty cycle of 50 Hz can be used to prevent joule-heating. The developed voltage can be fed to a voltage amplifier and then to an ADC.

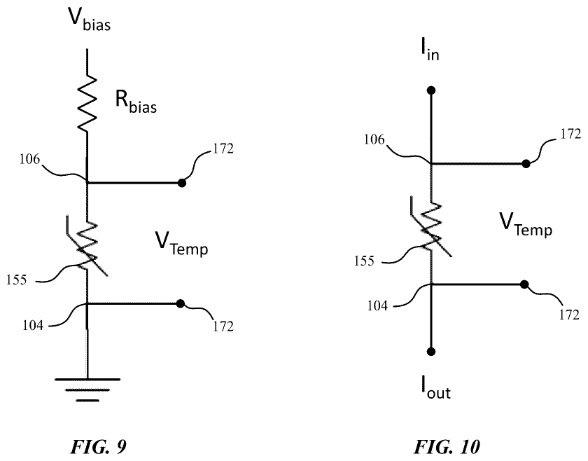

Referring now to FIG. 9 and FIG. 10 circuit diagrams are provided for two-terminal and four-terminal co-packaged via thermistors, respectively. In each embodiment, the terminals are made with reference to connections made to chip contact pads 172 connected to the serial path 155. Both circuit diagrams operate in accordance with a similar basic principle in that that voltage can be measured across opposite ends of the serial path 155 at the chip contact pads 172.

In order to measure voltage across the serial path 155, a reference voltage or current is supplied. In one embodiment, a reference voltage is supplied by a chip contact pad that is DC biased. In one implementation the reference voltage bias (Vbias), resistance bias (Rbias), ground, and voltage differential measurement (Vtemp) are all provided in a controller, such as an application specific integrated circuit (ASIC) or system on chip die. The reference voltage bias can also be shared within the MEMS structure. For example, the chip contact pad 172 coupled with resonator plug 160 can also provide a reference voltage for the via thermistor 102. In an exemplary two-terminal configuration a voltage source is coupled with the first contact terminal (e.g., coupled to resistive plug 106), and an electrical ground is coupled with the second contact terminal (e.g., bulk via 104) of a via thermistor 102 where the serial path exists through the first contact terminal to the second contact terminal. A similar relationship may exist between the first and last contact terminals for serially connected via thermistors 102. Furthermore, the serial path may exist in the opposite direction between the resistive plug and bulk via.

In an exemplary four-terminal configuration separate current inputs and outputs are provided to the serial path 155. For example, a current input (which may also be connected is its own chip contact pad) is coupled with a first contact terminal (e.g., coupled to resistive plug 106), and a current output (which may also be connected to its own chip contact pad) is coupled with the second contact terminal (e.g., bulk via 104) of a via thermistor 102, where the serial path exists through the first contact terminal to the second contact terminal. A similar relationship may exist between the first and last contact terminals for serially connected via thermistors 102. Furthermore, the serial path may exist in the opposite direction between the resistive plug and bulk via.

In utilizing the various aspects of the embodiments, it would become apparent to one skilled in the art that combinations or variations of the above embodiments are possible for forming a MEMS resonator with co-packaged via thermistor. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration. Furthermore, it is to be appreciated that the figures have been provided for illustrational purposes and may not be to scale. Also, in the interest of conciseness and reducing the total numbers of figures, a given figure may be used to illustrate the features of more than one aspect of the disclosure, and not all elements in the figure may be required for a given aspect.

What is claimed is:

1. A MEMS device with co-packaged thermistor comprising:
a device layer including a resonator element;
a cap layer bonded to the device layer, the cap layer including a via thermistor comprised of:
a bulk via extending through a thickness of the cap layer;
a resistive plug extending through the thickness of the cap layer; and
an insulator liner layer between the bulk via and the resistive plug; and
a conductive cap covering the resistive plug and a portion of the bulk via;
a first contact terminal in electrical connection with the bulk via; and
a second contact terminal in electrical connection with the resistive plug.

2. The MEMS device of claim 1, wherein the bulk via laterally surrounds the resistive plug.

3. The MEMS device of claim 1, wherein the bulk via comprises single crystalline silicon.

4. The MEMS device of claim 3, wherein the resistive plug comprises polysilicon.

5. The MEMS device of claim 4, wherein the polysilicon is doped with a dopant concentration of at least 1×10¹⁹ cm⁻³.

6. The MEMS device of claim 4, wherein the conductive cap comprises polysilicon.

7. The MEMS device of claim 6, wherein the conductive cap is within an upper cavity in the cap layer.

8. The MEMS device of claim 1, wherein the cap layer comprises a second via thermistor, wherein the via thermistor and the second via thermistor are serially connected.

9. The MEMS device of claim 8:
wherein the via thermistor is comprised of:
a bulk via extending through a thickness of the cap layer;
a resistive plug extending through the thickness of the cap layer; and
an insulator liner layer between the bulk via and the resistive plug; and
a conductive cap covering the resistive plug and portion of the bulk via; and
wherein the second via thermistor is comprises of:
a second bulk via extending through the thickness of the cap layer;
a second resistive plug extending through the thickness of the cap layer; and
a second insulator liner layer between the second bulk via and the second resistive plug; and
a second conductive cap covering the second resistive plug and a portion of the second bulk via; and
wherein the bulk via laterally surrounds the resistive plug and the second bulk via laterally surrounds the second resistive plug.

10. The MEMS device of claim 8, further comprising a metal trace routing on top of the cap layer connecting the via thermistor to the second via thermistor.

11. The MEMS device of claim 1, wherein the device layer further comprises an in-plane capacitive drive electrode laterally adjacent to the resonator element.

12. The MEMS device of claim 11, wherein the cap layer further comprises a drive electrode plug bonded to the in-plane capacitive drive electrode.

13. The MEMS device of claim 1, wherein the cap layer further comprises an out-of-plane drive electrode directly over the resonator element.

14. The MEMS device of claim 1, wherein the device layer is homogenously doped with a dopant concentration on an order of 10¹⁹ cm⁻³ and higher.

15. The MEMS device of claim 1, wherein the cap layer and the device layer are both doped, and the cap layer has a dopant concentration that is less than or equal to a dopant concentration of the device layer.

16. The MEMS device of claim 1, further comprising a current input coupled with the first contact terminal, and current output coupled the second contact terminal.

17. The MEMS device of claim 1, further comprising a voltage source coupled with the first contact terminal, and an electrical ground coupled with the second contact terminal.

18. The MEMS device of claim 1, further comprising:
a support layer including a lower cavity;
wherein the device layer is bonded to the support layer, the resonator element directly over the lower cavity.

19. The MEMS device of claim 1, further comprising an isolation trench formed through the cap layer and defining the bulk via, wherein the isolation trench is filled with:
an interior insulator liner layer laterally adjacent to the bulk via;
an exterior insulator liner layer laterally adjacent to a portion of the cap layer outside of the via thermistor; and
a resistive fill material between the interior insulator liner layer and the exterior insulator liner layer.

20. The MEMS device of claim 19, wherein the resistive plug is characterized by a lateral width that is greater than a lateral width of the resistive fill material between the interior insulator liner layer and the exterior insulator liner layer.

21. The MEMS device of claim 19, wherein the resistive plug and the resistive fill material have a same dopant concentration.

22. A method of measuring temperature of a MEMS device:
measuring voltage across a via thermistor while applying current through the thermistor;
amplifying the voltage with a voltage amplifier;
feeding the amplified voltage to an analog-to-digital converter (ADC) to extract a temperature value;
wherein the MEMS device comprises:
a device layer; and
a cap layer bonded to the device layer, the cap layer including the via thermistor.

23. The method of claim 22, wherein the via thermistor comprises:
a bulk via extending through a thickness of the cap layer;
a resistive plug extending through the thickness of the cap layer;
an insulator liner layer between the bulk via and the resistive plug; and
a conductive cap covering the resistive plug and a portion of the bulk via.

24. The method of claim 23, wherein the bulk via laterally surrounds the resistive plug.

25. The method of claim 23, wherein the bulk via comprises single crystalline silicon and the resistive plug comprises polysilicon.
